(19) United States
(12) Patent Application Publication
(10) Pub. No.: US 2021/0184454 A1
(43) Pub. Date: Jun. 17, 2021

(54) BANDWIDTH-BOOSTED BIDIRECTIONAL SERIAL BUS BUFFER CIRCUIT

(71) Applicant: TEXAS INSTRUMENTS INCORPORATED, Dallas, TX (US)

(72) Inventors: Kyle Edward ADDINGTON, Dallas, TX (US); Jonathan Lee VALDEZ, Bedford, TX (US)

(21) Appl. No.: 16/934,135

(22) Filed: Jul. 21, 2020

Related U.S. Application Data
(60) Provisional application No. 62/947,553, filed on Dec. 13, 2019.

(51) Int. Cl. H02H 3/44; H03K 5/22

(52) U.S. Cl. CPC H02H 3/44; H03K 5/22

(57) ABSTRACT

A serial bus buffer circuit includes a master input-output terminal, a slave input-output terminal, a switched resistor circuit, and a switch control circuit. The switched resistor circuit is configured to provide a low impedance connection between the master input-output terminal and the slave input-output terminal. The switch control circuit is coupled to the switched resistor circuit, and is configured to enable the low impedance connection based on voltage at the master input-output terminal and voltage at the slave input-output terminal.

### CROSS-REFERENCE TO RELATED APPLICATION

This application claim priority to U.S. Provisional Application No. 62/947,553, filed Dec. 13, 2019, entitled “Bandwidth-Boosted Bidirectional I2C Buffer Architecture,” which is hereby incorporated herein by reference in its entirety.

### BACKGROUND

Serial buses, such as the inter-integrated circuit (I²C) bus, are widely used to connect systems of devices. For example, the I²C bus is used to provide communication between a master device and one or more slave devices. In such applications; the capacitance added to the serial bus by the slave devices may be large enough to significantly degrade signal transition times and cause violation of serial bus timing specifications.

### SUMMARY

A serial bus buffer circuit that includes a switchable low impedance path to reduce transients (glitches) on the bus signals is disclosed herein. In one example, a serial bus buffer circuit includes a master input-output terminal, a slave input-output terminal, a first switch, a second switch, a resistor, and a switch control circuit. The first switch includes a first terminal, a second terminal, and a control terminal. The first terminal is coupled to the master input-output terminal. The resistor includes a first terminal and a second terminal. The first terminal of the resistor is coupled to the second terminal of the first switch. The second switch includes a first terminal, a second terminal, and a control terminal. The first terminal of the second switch is coupled to the second terminal of the resistor. The second terminal of the second switch is coupled to the slave input-output terminal. The switch control circuit is coupled to the master input-output terminal, the slave input-output terminal, the control terminal of the first switch, and the control terminal of the second switch.

In another example, a serial bus buffer circuit includes a master input-output terminal, a slave input-output terminal, a switched resistor circuit, and a switch control circuit. The switched resistor circuit is configured to provide a low impedance connection between the master input-output terminal and the slave input-output terminal. The switch control circuit is coupled to the switched resistor circuit, and is configured to enable the low impedance connection based on voltage at the master input-output terminal and voltage at the slave input-output terminal.

In a further example, a method includes monitoring a first voltage at a master input-output terminal of a serial bus buffer circuit, and monitoring a second voltage at a slave input-output terminal of the serial bus buffer circuit. The first voltage and the second voltage are compared to a low logic level threshold. The low impedance connection between the master input-output terminal and the slave input-output terminal is enabled responsive to the first voltage or the second voltage being below the low logic threshold.

### BRIEF DESCRIPTION OF THE DRAWINGS

For a detailed description of various examples, reference will now be made to the accompanying drawings in which:

FIG. 1 shows a block diagram for an example serial bus system that includes a serial bus buffer circuit;

FIG. 2 shows a block diagram for an example serial bus buffer circuit that includes transient reduction circuitry;

FIG. 3 shows a glitch produced at a handoff in a serial bus buffer circuit that lacks transient reduction circuitry; and

FIG. 4 shows a glitch produced at a handoff in a serial bus buffer circuit that includes transient reduction circuitry; and

FIG. 5 shows a flow diagram for an example method for reducing transients in a serial bus buffer circuit.

### DETAILED DESCRIPTION

Serial bus buffer circuits are used to reduce capacitive loading and improve signal integrity in serial bus systems (e.g., I²C bus systems). Serial bus buffers that lack very high bandwidth, produce glitches during handoff transitions (such as acknowledge, clock-stretching, etc.). Some serial bus buffer circuit implementations provide good glitch rejection, but poor isolation between serial bus devices. Other serial bus circuit implementations provide good isolation between serial bus devices, but are too slow to provide good glitch rejection.

The serial bus buffer circuits of the present disclosure include a compensation circuit that dynamically switches a low impedance compensation path between the master and slave terminals of the serial bus buffer circuit when handoff conditions are detected. The low impedance compensation path increases the bandwidth of the serial bus buffer circuit to reduce the amplitude and duration of handoff glitches. The serial bus buffer circuits also provide good master-slave isolation when the low-impedance compensation path is disabled.

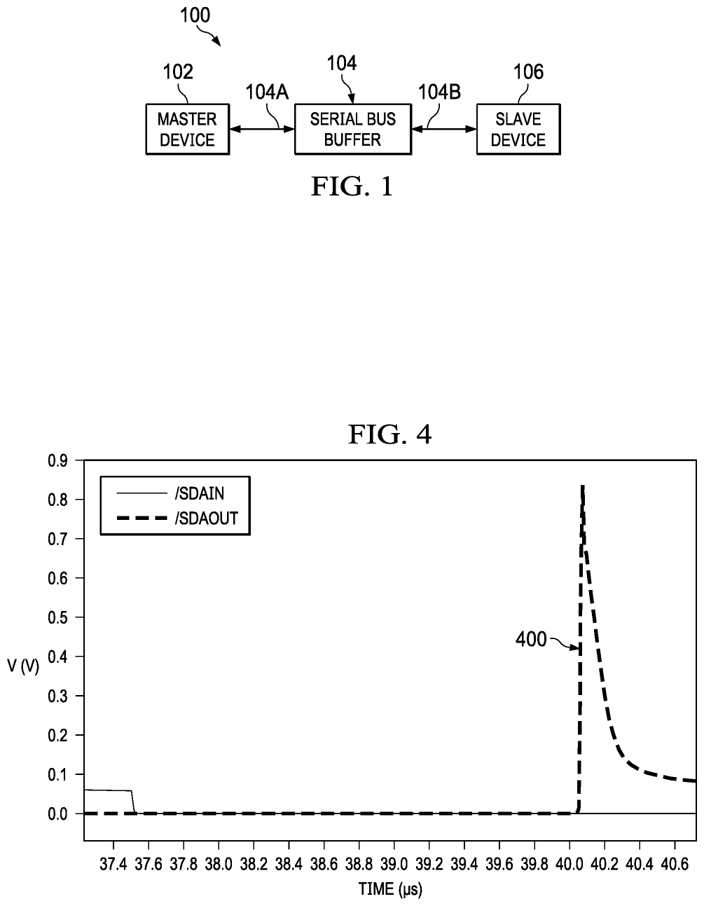

FIG. 1 shows a block diagram for an example serial bus system 100 that includes a serial bus buffer circuit. The serial bus system 100 includes a master device 102, a serial bus buffer circuit 104, and a slave device 106. In some implementations of the serial bus system 100, the master device 102 is an I2C master, the slave device 106 is an I2C slave, and the serial bus buffer circuit 104 is an I2C serial bus buffer circuit. The master device 102 is coupled to a master input-output terminal 104A of the serial bus buffer circuit 104, and the slave device 106 is coupled to a slave input-output terminal 104B of the serial bus buffer circuit 104. The serial bus buffer circuit 104 provides isolation and increased drive between the master device 102 and the slave device 106. The serial bus buffer circuit 104 includes a low impedance compensation path between the master input-output terminal 104A and the slave input-output terminal 104B. The serial bus buffer circuit 104 detects potential handoffs and enables the low impedance compensation path when a potential handoff is detected to reduce glitch amplitude and duration. When handoff conditions are not present, the serial bus buffer circuit 104 disables the low impedance compensation path to provide increased isolation between the master input-output terminal 104A and the slave input-output terminal 104B.

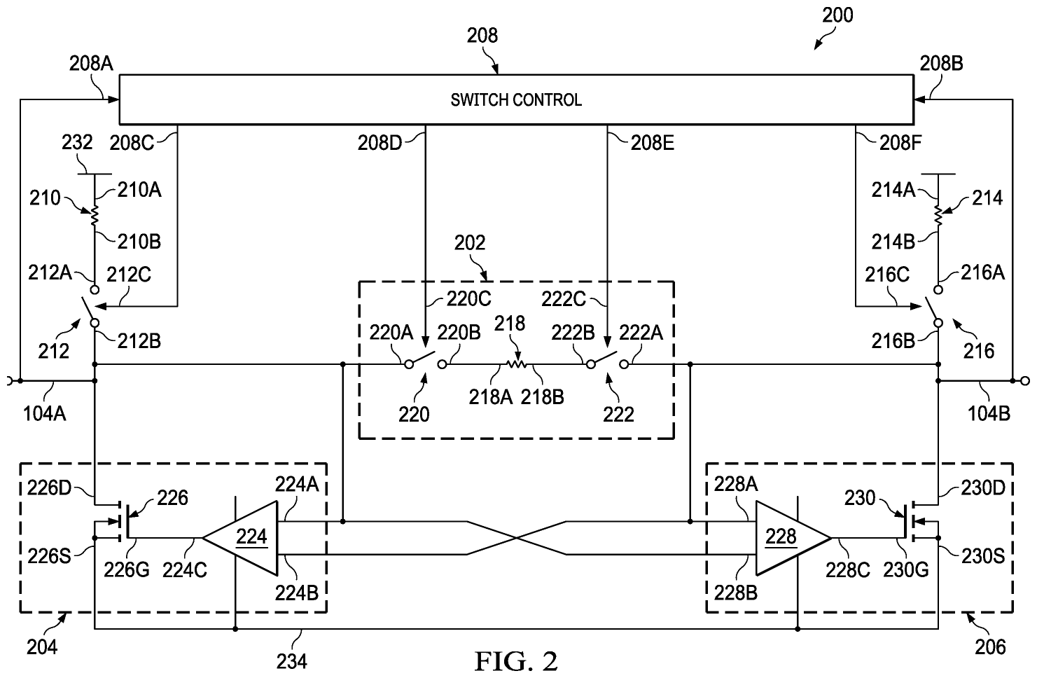

FIG. 2 shows a block diagram for an example serial bus buffer circuit 200 that includes transient reduction circuitry. The serial bus buffer circuit 200 is an implementation of the serial bus buffer circuit 104. The serial bus buffer circuit 200 includes a switched resistor circuit switched resistor circuit 202, a drive circuit 204, a drive circuit 206, a switch control circuit 208, a resistor 210, a switch 212, a resistor 214, and a switch 216. The switched resistor circuit 202 is an implementation of the low impedance compensation path of the serial bus buffer circuit 104. The switched resistor circuit 202 includes a resistor 218, a switch 220, and a switch 222. The switch 220 and the switch 222 are closed to connect the resistor 218 to the master input-output terminal 104A and the slave input-output terminal 104B and enable a low impedance connection between the master input-output terminal 104A and the slave input-output terminal 104B. The switch 220 and the switch 222 are opened to isolate the master input-output terminal 104A from the slave input-output terminal 104B.

A terminal 220A of the switch 220 is coupled to the master input-output terminal 104A. A terminal 220B of the switch 220 is coupled to the terminal 218A of the resistor 218. A terminal 218B of the resistor 218 is coupled to the terminal 222B of the switch 222. A terminal 222A of the switch 222 is coupled to the slave input-output terminal 104B.

The switch control circuit 208 monitors the voltages on the master input-output terminal 104A and the slave input-output terminal 104B and controls the switched resistor circuit 202 based on the voltages. The switch control circuit 208 includes a terminal 208A coupled to the master input-output terminal 104A and a terminal 208B coupled to the slave input-output terminal 104B. The switch control circuit 208 also includes a terminal 208D coupled to a control terminal 220C of the switch 220, and a terminal 208E coupled to a control terminal 222C of the switch 222. The switch control circuit 208 includes analog circuitry, such as analog comparators, that compares the voltages on the master input-output terminal 104A and the slave input-output terminal 104B to a logic low voltage of the serial bus buffer circuit 200 (e.g., 30% of the power supply voltage at a power supply terminal 232). If the switch control circuit 208 detects a logic low voltage at the master input-output terminal 104A or the slave input-output terminal 104B, the switch control circuit 208 closes the switch 220 and the switch 222 to enable the low impedance connection between the master input-output terminal 104A and the slave input-output terminal 104B.

The switch control circuit 208 also includes analog circuitry, such as analog comparators that compares the voltages on the master input-output terminal 104A and the slave input-output terminal 104B to a predetermined voltage (e.g., 700 millivolts (mv)), and includes slew rate detection circuitry that measures the slew rate of the voltages at the master input-output terminal 104A and slave input-output terminal 104B. If the voltage at the master input-output terminal 104A and the voltage at the slave input-output terminal 104B exceed the predetermined voltage, and the slew rate of the voltage at the master input-output terminal 104A and of the voltage at the slave input-output terminal 104B exceed a predetermined slew rate (e.g., 1.2 volts per microsecond), then the switch control circuit 208 opens the switch 220 and the switch 222 to disable the low impedance connection between the master input-output terminal 104A and the slave input-output terminal 104B.

The switch control circuit 208 also includes digital circuitry, such as state machine circuitry, that controls (opens and closes as described above) the switch 220 and the switch 222 based on the outputs of the analog circuitry and the current state of the switches 220 and 222.

The drive circuit 204 includes an amplifier 224 and a transistor 226. The transistor 226 is an N-channel metal oxide semiconductor field effect transistor (MOSFET) in some implementations of the drive circuit 204. A non-inverting input terminal 224A of the amplifier 224 is coupled to the master input-output terminal 104A, and an inverting input terminal 224B of the amplifier 224 is coupled to the slave input-output terminal 104B. An output terminal 224C of the amplifier 224 is coupled to the gate terminal 226G of the transistor 226. A source terminal 226S of the transistor 226 is coupled to a ground terminal 234. A drain terminal 226D of the transistor 226 is coupled to the master input-output terminal 104A. The amplifier 224 turns on the transistor 226 to pull down the master input-output terminal 104A when the voltage at the master input-output terminal 104A is greater than the voltage at the slave input-output terminal 104B.

The drive circuit 206 includes an amplifier 228 and a transistor 230. The transistor 230 is an N-channel MOSFET in some implementations of the drive circuit 206. A non-inverting input terminal 228A of the amplifier 228 is coupled to the slave input-output terminal 104B, and an inverting input terminal 228B of the amplifier 228 is coupled to the master input-output terminal 104A. An output terminal 228C of the amplifier 228 is coupled to the gate terminal 230G of the transistor 230. A source terminal 230S of the transistor 230 is coupled to the ground terminal 234. A drain terminal 230D of the transistor 230 is coupled to the slave input-output terminal 1046. The amplifier 228 turns on the transistor 230 to pull down the slave input-output terminal 104B when the voltage at the slave input-output terminal 104B is higher than the voltage at the master input-output terminal 104A.

The switch 212 couples the resistor 210 to the master input-output terminal 104A to pull up the master input-output terminal 104A under control of the switch control circuit 208. The resistor 210 includes a terminal 210A coupled to the power supply terminal 232 and a terminal 210B coupled to a terminal 212A of the switch 212. A terminal 212B of the switch 212 is coupled to the master input-output terminal 104A, and a control terminal 212C of the switch 212 is coupled to a terminal 208C of the switch control circuit 208. The switch control circuit 208 closes the switch 212 based on the voltage at the master input-output terminal 104A exceeding a threshold (e.g., 30% of the voltage at the power supply terminal 232) to decrease the rise time of the voltage of the master input-output terminal 104A.

The switch 216 couples the resistor 214 to the slave input-output terminal 104B to pull up the master input-output terminal 104A under control of the switch control circuit 208. The resistor 214 includes a terminal 214A coupled to the power supply terminal 232 and a terminal 214B coupled to a terminal 216A of the switch 216. A terminal 216B of the switch 216 is coupled to the slave input-output terminal 104B, and a control terminal 216C of the switch 216 is coupled to a terminal 208F of the switch control circuit 208. The switch control circuit 208 closes the switch 216 based on the voltage at the slave input-output terminal 104B exceeding a threshold (e.g., 30% of the voltage at the power supply terminal 232) to decrease the rise time of the voltage of the slave input-output terminal 104B.

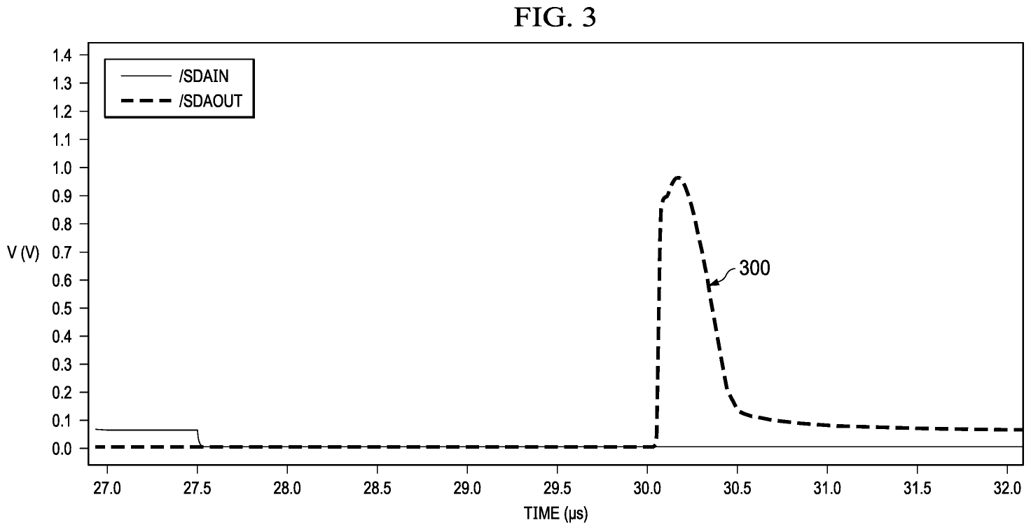

FIG. 3 shows a glitch produced at a handoff in a serial bus buffer circuit that lacks transient reduction circuitry. The glitch 300 has maximum amplitude of about 965 my and is greater than about 300 my in amplitude for about 350 nanoseconds (ns).

FIG. 4 shows a glitch produced at a handoff by an implementation of the serial bus buffer circuit 104. The glitch 400 has maximum amplitude of less than 830 my and is greater than about 300 my in amplitude for less than about 140 nanoseconds (ns). Thus, the serial bus buffer circuit 104 substantially reduces the amplitude and duration of transient glitches on the serial bus relative to a serial bus buffer circuit that lacks transient reduction circuitry.

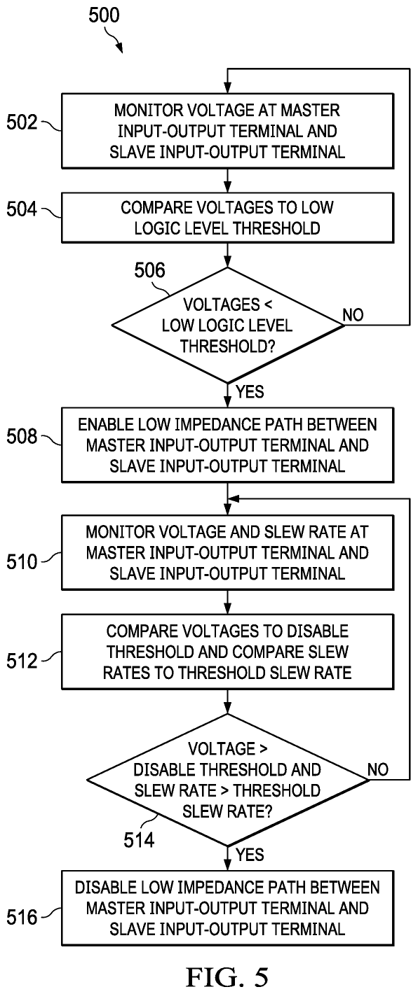

FIG. 5 shows a flow diagram for an example method 500 for reducing transients in a serial bus buffer circuit. Though depicted sequentially as a matter of convenience, at least some of the actions shown can be performed in a different order and/or performed in parallel. Additionally, some implementations may perform only some of the actions shown. Operations of the method 500 are performed by an implementation of the serial bus buffer circuit 200.

In block 502, the switch control circuit 208 monitors the voltage at the master input-output terminal 104A and the voltage at the slave input-output terminal 104B.

In block 504, the switch control circuit 208 compares the voltage at the master input-output terminal 104A to a low logic level threshold (e.g., 30% of the voltage at the power supply terminal 232), and compares the voltage at the slave input-output terminal 104B to the low logic level threshold.

In block 506, if the voltage at the master input-output terminal 104A is less than the low logic level threshold, or the voltage at the slave input-output terminal 104B is less than the low logic level threshold, then the method continues in block 508. If the voltage at the master input-output terminal 104A is not less than the low logic level threshold, and the voltage at the slave input-output terminal 104B is not less than the low logic level threshold, then the method continues in block 502.

In block 508, the switch control circuit 208 enables a low impedance path between the master input-output terminal 104A and the slave input-output terminal 104B. Enabling the low impedance path includes closing the switch 220 and the switch 222. Handoff transients are reduced while the low impedance path is enabled.

In block 510, the switch control circuit 208 monitors the voltage at the master input-output terminal 104A and the voltage at the slave input-output terminal 104B, and monitors the slew rate of the voltage at the master input-output terminal 104A and the slew rate of the voltage at the slave input-output terminal 104B.

In block 512, the switch control circuit 208 compares the voltage at the master input-output terminal 104A to a predetermined threshold (a disable threshold, e.g., 700 mv), compares the voltage at the slave input-output terminal 104B to the predetermined threshold, compares the slew rate of voltage at the master input-output terminal 104A to a threshold slew rate (e.g., 1.2 v/us), and compares the slew rate of voltage at the slave input-output terminal 104B to the threshold slew rate.

In block 514, if the voltage at the master input-output terminal 104A is greater than the predetermined threshold, the slew rate of the voltage at the master input-output terminal 104A is greater than the threshold slew rate, the voltage at the slave input-output terminal 104B is greater than the predetermined threshold, and the slew rate of the voltage at the slave input-output terminal 104B is greater than the threshold slew rate, then the method 500 continues in block 516. If the voltage at the master input-output terminal 104A is not greater than the predetermined threshold, the slew rate of the voltage at the master input-output terminal 104A is not greater than the threshold slew rate, the voltage at the slave input-output terminal 104B is not greater than the predetermined threshold, or the slew rate of the voltage at the slave input-output terminal 104B is not greater than the threshold slew rate, then the method 500 continues in block 510.

In block 516, the switch control circuit 208 disables the low impedance path between the master input-output terminal 104A and the slave input-output terminal 104B. Disabling the low impedance path includes opening the switch 220 and the switch 222.

The term “couple” is used throughout the specification. The term may cover connections, communications, or signal paths that enable a functional relationship consistent with the description of the present disclosure. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

Modifications are possible in the described embodiments, and other embodiments are possible, within the scope of the claims.

What is claimed is:

1. A serial bus buffer circuit, comprising:
a master input-output terminal;
a slave input-output terminal;
a first switch comprising:
a first terminal coupled to the master input-output terminal;
a second terminal; and
a control terminal;
a resistor comprising:
a first terminal coupled to the second terminal of the first switch; and
a second terminal;
a second switch comprising:
a first terminal coupled to the second terminal of the resistor;
a second terminal coupled to the slave input-output terminal; and
a control terminal; and
a switch control circuit coupled to the master input-output terminal, the slave input-output terminal, the control terminal of the first switch, and the control terminal of the second switch.

2. The serial bus buffer circuit of claim 1, further comprising:
an amplifier comprising:
a non-inverting input terminal coupled to the first terminal of the first switch;
an inverting input terminal coupled to the first terminal of the second switch; and
an output terminal.

3. The serial bus buffer circuit of claim 2, further comprising:
a transistor comprising:
a first terminal coupled to the master input-output terminal;
a second terminal coupled to a ground terminal; and
a third terminal coupled to the output terminal of the amplifier.

4. The serial bus buffer circuit of claim 1, further comprising:
an amplifier comprising:
a non-inverting input terminal coupled to the first terminal of the second switch;
an inverting input terminal coupled to the first terminal of the first switch; and
an output terminal.

5. The serial bus buffer circuit of claim 4, further comprising:
a transistor comprising:
a first terminal coupled to the slave input-output terminal;
a second terminal coupled to a ground terminal; and
a third terminal coupled to the output terminal of the amplifier.

6. The serial bus buffer circuit of claim 1, wherein:
the resistor is a first resistor; and
the serial bus buffer circuit comprises:
a second resistor comprising:
a first terminal coupled to a power supply terminal; and
a second terminal; and
a third switch comprising:
a first terminal coupled to the second terminal of the second resistor;
a second terminal coupled to the master input-output terminal; and
a control terminal coupled to the switch control circuit.

7. The serial bus buffer circuit of claim 1, wherein:
the resistor is a first resistor; and
the serial bus buffer circuit comprises:
a second resistor comprising:
a first terminal coupled to a power supply terminal; and
a second terminal; and
a third switch comprising:
a first terminal coupled to the second terminal of the second resistor;
a second terminal coupled to the slave input-output terminal; and
a control terminal coupled to the switch control circuit.

8. A serial bus buffer circuit, comprising:
a master input-output terminal;
a slave input-output terminal;
a switched resistor circuit configured to provide a low impedance connection between the master input-output terminal and the slave input-output terminal; and
a switch control circuit coupled to the switched resistor circuit and configured to enable the low impedance connection based on voltage at the master input-output terminal and voltage at the slave input-output terminal.

9. The serial bus buffer circuit of claim 8, wherein the switch control circuit is configured to enable the low impedance connection based on detection of a low logic voltage level at the master input-output terminal or detection of the low logic voltage level at the slave input-output terminal.

10. The serial bus buffer circuit of claim 8, wherein the switch control circuit is configured to disable the low impedance connection based on detection of a first voltage exceeding a threshold at the master input-output terminal and a second voltage exceeding the threshold at the slave input-output terminal.

11. The serial bus buffer circuit of claim 10, wherein the switch control circuit is configured to disable the low impedance connection based on a slew rate of the first voltage at the master input-output terminal exceeding a predetermined slew rate, and a slew rate of the second voltage at the slave input-output terminal exceeding the predetermined slew rate.

12. The serial bus buffer circuit of claim 8, wherein:
the switched resistor circuit comprises:
a first switch;
a resistor coupled to the first switch; and
a second switch coupled to the resistor; and
the switch control circuit is configured to close the first switch and the second switch to enable the low impedance connection.

13. The serial bus buffer circuit of claim 12, wherein the switch control circuit is configured to open the first switch and the second switch to disable the low impedance connection.

14. The serial bus buffer circuit of claim 8, further comprising a drive circuit configured to drive the master input-output terminal based the voltage at the master input-output terminal and the voltage at the slave input-output terminal.

15. The serial bus buffer circuit of claim 8, further comprising a drive circuit configured to drive the slave input-output terminal based the voltage at the master input-output terminal and the voltage at the slave input-output terminal.

16. A method, comprising:
monitoring a first voltage at a master input-output terminal of a serial bus buffer circuit;
monitoring a second voltage at a slave input-output terminal of the serial bus buffer circuit;
comparing the first voltage and the second voltage to a low logic level threshold; and
enabling a low impedance connection between the master input-output terminal and the slave input-output terminal responsive to the first voltage or the second voltage being below the low logic threshold.

17. The method of claim 16, wherein the enabling comprises:
closing a first switch to connect a resistor to the master input-output terminal; and
closing a second switch to connect the resistor to the slave input-output terminal.

18. The method of claim 16, further comprising:
comparing the first voltage and the second voltage to a disable threshold; and
disabling the low impedance connection between the master input-output terminal and the slave input-output terminal responsive to the first voltage and the second voltage being above the disable threshold.

19. The method of claim 18, further comprising:
monitoring a slew rate of the first voltage;
monitoring a slew rate of the second voltage;
comparing the slew rate of the first voltage and the slew rate of the second voltage to a threshold slew rate; and
disabling the low impedance connection between the master input-output terminal and the slave input-output terminal responsive to slew rate of the first voltage and the slew rate of the second voltage exceeding the threshold slew rate.

20. The method of claim 18, wherein the disabling comprises:
opening a first switch to disconnect a resistor from the master input-output terminal; and
opening a second switch to disconnect the resistor from the slave input-output terminal.
